(19) United States
(12) Patent Application Publication
(10) Pub. No.: US 2014/0185785 A1
(43) Pub. Date: Jul. 3, 2014

(54) COLLABORATIVE VOLUME MANAGEMENT

(71) Applicant: INTERNATIONAL BUSINESS MACHINES CORPORATION, Armonk, NY (US)

(72) Inventors: Wendell J. Bouknight, JR., Clayton, NC (US); Erik W. Hochstedt, Holly Springs, NC (US); Thai T. La, Durham, NC (US); Dana L. Price, Cary, NC (US)

(73) Assignee: INTERNATIONAL BUSINESS MACHINES CORPORATION, Armonk, NY (US)

(21) Appl. No.: 13/733,280

(22) Filed: Jan. 3, 2013

(51) Int. Cl. H03G 3/20; H04M 3/56

(52) U.S. Cl. CPC H03G 3/20; H04M 3/56
USPC 379/202.01

(57) ABSTRACT

Exemplary embodiments provide collaborative call management wherein during a multi-participant audio communication, volume adjustments made on participant devices for a specific speaker are detected and passed to a conference server to generate collaborative volume feedback; and using the collaborative volume feedback to adjust a volume level of the specific speaker for all participants of the audio communication.

### BACKGROUND

Volume levels during multi-participant audio communications, such as telephone conferences, radio broadcasts, webinars, and the like, can vary greatly among individual speakers, making it difficult for the participants to hear the audio content given the different volumes of each of the speakers. For example, within a single conference call, one speaker participating from home may be too soft to hear well, another speaker may be very loud, and yet another speaker may be somewhere in the middle.

Individual participants listening on the call may use volume up and down controls on their communication device (e.g., phone, a tablet, computer, etc.) at different points in the call because the current speaker may be either too soft to hear, or too loud for pleasant listening. A solution is needed where the input from the listening participants translates into improved audio transmission.

Several conventional solutions have been attempted. The most obvious solution is for individual participants to manually adjust the volume on their device for a particular speaker. However this requires each participant to make individual volume adjustments that other participants do not benefit from. In addition, when another speaker talks, the participant's volume level may be adjusted poorly for the new speaker, requiring subsequent adjustment adjustments.

Another solution requires the participants to interrupt the current speaker to request the speaker to improve their volume level, but this tends to distract from the actual content being provided.

In audio communications having a moderator or teleconference operator, the moderator may adjust the volume level of each speaker's line, but this demands the moderator's attention and actions to make volume adjustments to each line unified across all participants whether or not the adjustments are appropriate for each participant.

Accordingly, it would be desirable to provide improved volume management for audio communications.

### BRIEF SUMMARY

The exemplary embodiment provides methods and systems for collaborative call management. Aspects of exemplary embodiment include during a multi-participant audio communication, detecting volume adjustments made on participant devices for a specific speaker, and passing the volume adjustments to a conference server to generate collaborative volume feedback; and using the collaborative volume feedback to adjust a volume level of the specific speaker for all participants of the audio communication.

According to the method and system disclosed herein, the exemplary embodiment uses the volume feedback from call participants who have modified the volume level of particular speakers on their own devices in a crowdsourcing manner, such that a conference server can fine-tune the volume levels for each speaker to enhance call quality for all of the participants.

### BRIEF DESCRIPTION OF SEVERAL VIEWS OF THE DRAWINGS

FIG. 1 is a diagram illustrating one embodiment of a collaborative volume management system.

FIG. 2 is a flow diagram illustrating one embodiment of a process for collaborative volume management.

### DETAILED DESCRIPTION

The exemplary embodiment relates to collaborative volume management. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations. Phrases such as “exemplary embodiment”, “one embodiment” and “another embodiment” may refer to the same or different embodiments. The embodiments will be described with respect to systems and/or devices having certain components. However, the systems and/or devices may include more or less components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein.

The exemplary embodiments provide collaborative volume management for multi-participant audio communications where individual volume adjustments made on participant devices for a particular speaker are detected and used as group volume feedback. The group volume feedback is then used to adjust the volume of that speaker for all participants when the number volume adjustments meet a threshold level according to a collaborative aggregation policy.

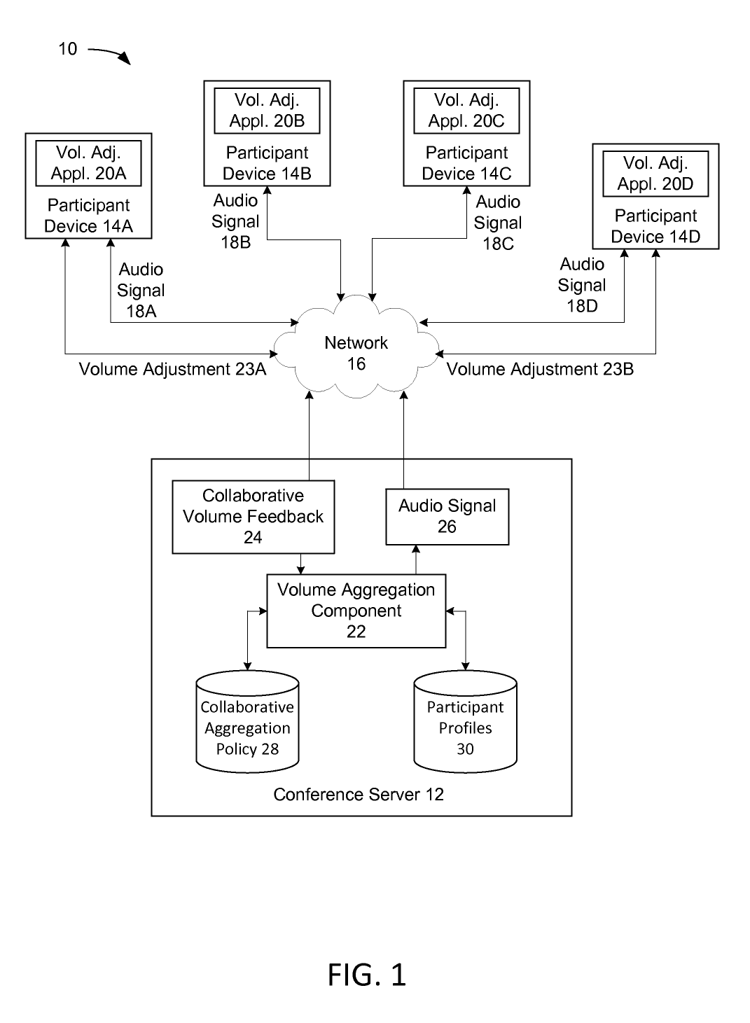

FIG. 1 is a diagram illustrating one embodiment of a collaborative volume management system. According to the exemplary embodiment, the collaborative volume management system 10 comprises a conference server 12 that is in communication with multiple participant devices 14 (shown as 14A, 14B, 14C and 14D) over a network 16. In one embodiment, the network 16 may comprise a public network, such as the Internet, or a private network, such of the corporate intranet. In one embodiment, the conference server 12 provides multi-participant audio communications for participants using the participant devices 14. As used herein, examples of multi-participant audio communications include, but are not limited to, conference calls or teleconferences, video conferences, radio broadcasts, web conferences, and the like.

The conference server 12 may be associated with a central phone number, a web address, and/or an IP address. The conference server 12 may optionally include a conference bridge (not shown) that can answer multiple calls simultaneously. Typically, individual participants use their own participant devices 14 to call into the central phone number to participate in the audio communication with other participants, or optionally, a moderator may call each participant. The participant devices 14 preferably include voice over Internet Protocol (VoIP) capability and may exist in various forms, including a telephone, a personal computer (PC), (e.g., desktop, laptop, or notebook), a set-top box, a game system, a web-enabled TV and the like.

During the call, the conference server 12 sends and receives audio signals 18 (shown as 18A, 18B, 18C, and 18D) from/to the participant devices 14, and one or more of the participants may also become speakers. If the audio communication comprises a web conference, then the conference server 12 may stream video in addition to streaming an audio signal 26 to the participant devices 14. As audio signals may vary among the participant devices 14, individual participants may use volume controls (not shown) on their participant device 14 to adjust the volume of different speakers (e.g., increase, decrease, or otherwise emphasize/deemphasize the speaker's voice). The conference server 12 is also capable of determining an identity of different speakers during the call. In typical conferencing systems, such volume adjustments by one participant do not benefit the other participants and/or may require a moderator to implement the volume adjustments.

According to the exemplary embodiment, the collaborative volume management system 10 further comprises a volume adjustment application 20 (shown as 20A, 20B, 20C, 20D) executing on the participant devices 14 and a volume aggregation component 22 executing on the conference server 12. The volume adjustment application 20 detects any volume adjustments made during the call and sends the volume adjustments 23 (shown as 23A and 23B) to the conference server 12 as collaborative volume feedback 24. The volume aggregation component 22 is configured to adjust the audio signal 26 for all participants based on the collaborative volume feedback 24, a collaborative aggregation policy 28, and optionally a set of participant profiles 30, as explained further below.

Both the conference server 12 and the participant devices 14 may include hardware components of typical computing devices (not shown), including at least one processor, input devices (e.g., keyboard, pointing device, microphone for voice commands, buttons, touch screen, etc.), and output devices (e.g., a display device, speakers, and the like). The conference server 12 and the participant devices 14 may include computer-readable media, e.g., memory and storage devices (e.g., flash memory, hard drive, optical disk drive, magnetic disk drive, and the like) containing computer instructions that implement the functionality disclosed when executed by the processor. The conference server 12 and the participant devices 14 may further include wired or wireless network communication interfaces for communication.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

The input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modems and Ethernet cards are just a few of the currently available types of network adapters.

Although the conference server 12 is shown as a single server, it should be understood that the functions of conference server 12 may be distributed over more than one server, and the functionality of software components may be implemented using a different number of software components. For example, the volume aggregation component 22 may be implemented as more than one component. In an alternative embodiment (not shown), the conference server 12 and the volume aggregation component 22 of FIG. 1 may be implemented as a virtual entity whose functions are distributed over multiple computers/serves. Although the collaborative aggregation policy 28 and the participant profile 30 are shown stored on the conference server 12, those with ordinary skill in the art will readily understand that the collaborative aggregation policy 28 and the participant profile 30 may be stored on a different server/computer and accessed by the conference server 12.

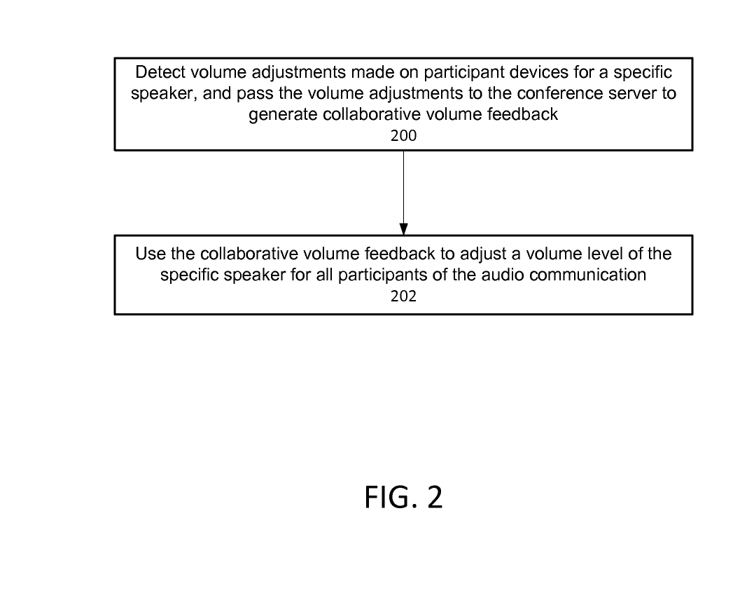

FIG. 2 is a flow diagram illustrating one embodiment of a process for collaborative volume management. The process may begin during a multi-participant audio communication, where the volume adjustment application 20 detects volume adjustments made on participant devices for a specific speaker, and passes the volume adjustments to the conference server to generate collaborative volume feedback (block 200). The volume aggregation component then uses the collaborative volume feedback to adjust a volume level of the specific speaker for all participants of the audio communication (block 202).

More specifically, the volume aggregation component 22 adjusts the volume level of the specific speaker when the collaborative volume feedback 24 comprises a threshold number of the volume adjustments according to the collaborative aggregation policy 28.

In one embodiment, the collaborative aggregation policy 28 may be configured to specify a first threshold, referred to as a percentage-of-participants threshold, that specifies a requisite number of participants from which the volume adjustments are received before the volume level is adjusted. For example, the volume aggregation component 22 may analyze the collaborative volume feedback 24 and determine that 6 out of 10 participants have raised their volume for speaker B, for instance. If the percentage-of-participants threshold is set to 50% per speaker, then the volume aggregation component 22 would raise the audio signal 26 since 66% of the participants “voted” to raise the volume.

In another embodiment, the collaborative aggregation policy 28 may be configured to further include a second threshold, referred to as a volume percentage threshold, that specifies what level each of the received volume adjustments 23 must exceed in order for the each of the volume adjustments 23 to count towards meeting the percentage-of-participants threshold. In the example above, where 6 out of 10 participants raised the volume for speaker B, the volume percentage threshold may specify that each of the volume adjustments 23 must be greater than 10%, for instance.

In yet a further embodiment, the collaborative aggregation policy 28 may be configured to include the third threshold, referred to as an adjustment percentage threshold, specifying a percent the volume aggregation component 22 adjusts the volume level of the audio signal 26. In one embodiment, the adjustment percentage threshold may be set to a fixed percentage, e.g., 5%, such that if the first and second thresholds are met, the volume aggregation component 22 adjust the audio signal 26 up or down by the fixed percentage.

In another embodiment, the adjustment percentage threshold may be configured as variable value. In one embodiment, the adjustment percentage threshold may be set to be an average, median, or some other computational-level of all the volume adjustments 23 received for a particular speaker that pass the percentage-of-participants threshold. In a further embodiment, the adjustment percentage threshold may also indicate that the volume aggregation component 22 may adjust (e.g., reduce the volume) the audio signal 26 for the participant devices that had manual volume adjustments (e.g., increase in volume) so the server-side volume increase to the audio signal 26 will not result in a double increase in gain for those participant devices 14.

In one embodiment, the percentage-of-participants threshold and the volume percentage threshold are implementation specific and may be set differently for different speakers. In one embodiment, the thresholds comprising the collaborative aggregation policy 28 may be configured by a conference service or administrator.

In another embodiment, the thresholds comprising the collaborative aggregation policy 28 may be modified based on the participant profile 30. That is, a history of volume adjustments made during one or more calls may be collected and used, such that the conference server 12 defines participant profiles 30 for any combination of the speakers, the participant devices 14, phone numbers, and the participants.

The following are examples of participant profiles 30.

A participant profile for participant John X could specify that the audio signal 26 be increased for all participants when John X becomes a speaker.

A participant profile for Mary Y and/or Mary Y's device may specify that the audio signal 26 be increased for Mary Y's participant device by 40% regardless of which participant is the speaker.

A participant profile for Bob Z and/or Bob Z's cell phone and office phone may specify that the audio signal 26 be increased for Bob Z's cell phone but not for his office phone.

In one embodiment, during a call the volume aggregation component 22 determines if any participant profiles 30 are associated with any current speakers, participant, and/or participant devices 14 on the call, and uses the applicable participant profiles 30 to set and/or modify the thresholds comprising the collaborative aggregation policy 28.

The following describes the collaborative volume management process in further detail. During a multi-participant audio communication, the conference server 12 receives one or more volume adjustments 23 from a particular participant device 14. The conference server 12 identifies the current speaker, and associates the volume adjustment 23 with the identified speaker. The conference server 12 may also collect and store other types of call data with each of the volume adjustments 23, including the sending participant device ID, the participant ID, any IP address and volume setting. Other types of collected call data may include time of day, and location of the participant device 14.

The volume aggregation component 22 aggregates the volume adjustment 23 from the particular participant device 14 with volume adjustments received from other participant devices of the participants corresponding to the identified speaker to generate the collaborative volume feedback 24.

The volume aggregation component 22 analyzes the collaborative volume feedback 24 to determine whether a number volume adjustments for the identified speaker have a volume change level exceeding the volume percentage threshold, and that these volume adjustments are received from a number of participant devices that exceed the percentage-of-participants threshold.

If so, the volume aggregation component 22 adjusts the gain of the audio signal 26 for the identified speaker for all participant devices on the call in accordance with the adjustment percentage threshold and the participant profiles 30.

When it is determined that the identified speaker has stopped speaking, the volume aggregation component 22 may return the audio signal 26 to a default base level.

The volume aggregation component 22 may also create new participant profiles and/or update existing participant profiles 30 with the new call data collected for the current call. The participant profiles 30 will then be accessed to adjust the audio signal of future calls.

The collaborative volume management system 10 aggregates the volume adjustments of multiple participants to regulate a given speaker's volume for all participants in the call. Thus, the collaborative volume management system 10 effectively enhances and improves the call quality and listening experience of all participants as a side effect of each participant's attempt to improve their own listening experience for a given speaker, while the volume preferences of a single participant will not directly impact the listening experience for all participants. The collaborative volume management is scalable in that the higher number of participants on the call that contribute to the collaborative volume feedback 24, the greater the chance that the audio signal 26 will be adjusted to a volume that enhances the call for all participants with little or no need for further volume adjustments.

In addition, the collaborative volume management system 10 is less complicated than traditional systems in that the collaborative volume management system 10 does not require a moderator, web page, or other permissions to provide mutually beneficial group volume adjustments.

A method and system for collaborative volume management has been disclosed. As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention have been described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

1. A method for collaborative volume management, the method performed by a software component executing on at least one processor, comprising:
during a multi-participant audio communication, detecting volume adjustments made on participant devices for a specific speaker, and passing the volume adjustments to a conference server to generate collaborative volume feedback;
analyzing, by the conference server, the collaborative volume feedback to determine whether a number volume adjustments for the specified speaker have a volume change level exceeding a volume percentage threshold, and whether the volume adjustments are received from a number of participant devices that exceed a percentage-of-participants threshold; and
if the percentage thresholds are met, using the collaborative volume feedback to adjust a volume level of the specific speaker for all participants of the audio communication.

2. The method of claim 1, further comprising: adjusting the volume level of the specific speaker when the collaborative volume feedback comprises a threshold number of the volume adjustments according to an aggregation policy.

3. The method of claim 2, wherein the aggregation policy includes the percentage-of-participants threshold specifying a requisite number of participants from which the volume adjustments are received before the volume level is adjusted.

4. The method of claim 2, wherein the aggregation policy includes the volume percentage threshold specifying what level each of the received volume adjustments must exceed in order for the volume adjustments to count towards meeting the percentage-of-participants threshold.

5. The method of claim 2, wherein the aggregation policy includes an adjustment percentage threshold specifying a percent the conference server adjusts the volume level of the audio signal.

6. The method of claim 5, further comprising: configuring the adjustment percentage threshold as at least one of an average and a median of the volume adjustments received that exceed the percentage-of-participants threshold.

7. The method of claim 1, further comprising: providing the conference server with an aggregation policy comprising a percentage-of-participants threshold, a volume percentage threshold, and an adjustment percentage thresholds, and modifying the percentage-of-participants threshold, the volume percentage threshold and the adjustment percentage threshold based on participant profiles.

8. The method of claim 1, further comprising: collecting a history of volume adjustments made during one or more calls and using the history of volume adjustments to define participant profiles for any combination of speakers, participant devices, phone numbers, and participants.

9. An executable software product stored on a non-transitory computer-readable medium containing program instructions for collaborative volume management, the program instructions for:
during a multi-participant audio communication, detecting volume adjustments made on participant devices for a specific speaker, and passing the volume adjustments to a conference server to generate collaborative volume feedback;
analyzing, by the conference server, the collaborative volume feedback to determine whether a number volume adjustments for the specified speaker have a volume change level exceeding a volume percentage threshold, and whether the volume adjustments are received from a number of participant devices that exceed a percentage-of-participants threshold; and
if the percentage thresholds are met, using the collaborative volume feedback to adjust a volume level of the specific speaker for all participants of the audio communication.

10. The executable software product of claim 9, further comprising program instructions for: adjusting the volume level of the specific speaker when the collaborative volume feedback comprises a threshold number of the volume adjustments according to an aggregation policy.

11. The executable software product of claim 10, wherein the aggregation policy includes a percentage-of-participants threshold specifying a requisite number of participants from which the volume adjustments are received before the volume level is adjusted.

12. The executable software product of claim 10, wherein the aggregation policy includes the volume percentage threshold specifying what level each of the received volume adjustments must exceed in order for the volume adjustments to count towards meeting the percentage-of-participant threshold.

13. The executable software product of claim 10, wherein the aggregation policy includes an adjustment percentage threshold specifying a percent the conference server adjusts the volume level of the audio signal.

14. The executable software product of claim 13, further comprising program instructions for: configuring the adjustment percentage threshold as at least one of an average and a median of the volume adjustments received that exceed the percentage-of-participants threshold.

15. The executable software product of claim 9, further comprising program instructions for: providing the conference server with an aggregation policy comprising a percentage-of-participants threshold, a volume percentage threshold, and an adjustment percentage thresholds, and modifying the percentage-of-participants threshold, the volume percentage threshold and the adjustment percentage special based on participant profiles.

16. The executable software product of claim 9, further comprising program instructions for: collecting a history of volume adjustments made during one or more calls and using the history of volume adjustments to define participant profiles for any combination of speakers, participant devices, phone numbers, and participants.

17. A system, comprising:
a plurality of participant devices, each of the plurality of participant devices having at least one processor for executing a first application; and
a server coupled to the participant devices over a network, the server providing a multi-participant audio communication for the plurality of participant devices, the server including a software component executed by at least one processor;
wherein during the multi-participant audio communication, first application on the plurality of participant devices detects volume adjustments made on the correspond participant device for a specific speaker, and passes the volume adjustments to a conference server to generate collaborative volume feedback; and
wherein the software component on the server analyzes the collaborative volume feedback to determine whether a number volume adjustments for the specified speaker have a volume change level exceeding a volume percentage threshold, and whether the volume adjustments are received from a number of participant devices that exceed a percentage-of-participants threshold; and if the percentage thresholds are met, uses the collaborative volume feedback to adjust a volume level of the specific speaker for all participants of the audio communication.

18. The system of claim 17, wherein the software component adjusts the volume level of the specific speaker when the collaborative volume feedback comprises a threshold number of the volume adjustments according to an aggregation policy.

19. The system of claim 18, wherein the aggregation policy is configured to include the percentage-of-participants threshold specifying a requisite number of participants from which the volume adjustments are received before the volume level is adjusted.

20. The system of claim 18, wherein the aggregation policy is configured to include the volume percentage threshold specifying what level each of the received volume adjustments must exceed in order for the volume adjustments to count towards meeting the percent-of-participants threshold.

21. The system of claim 18, wherein the aggregation policy is configured to include an adjustment percentage threshold specifying a percent the software component adjusts the volume level of the audio signal.

22. The system of claim 21, wherein the adjustment percentage threshold is configured as at least one of an average and a median of the volume adjustments received that exceed the percentage-of-participants threshold.

23. The system of claim 17, wherein the conference server is provided with an aggregation policy comprising a percentage-of-participants threshold, a volume percentage threshold, and an adjustment percentage threshold, wherein the percentage-of-participants threshold, the volume percentage threshold and the adjustment percentage threshold are modified based on participant profiles.

24. The system of claim 17, wherein the software component collects a history of volume adjustments made during one or more calls and uses the history of volume adjustments to define participant profiles for any combination of speakers, participant devices, phone numbers, and participants.
